(19) United States
(12) Patent Application Publication
(10) Pub. No.: US 2018/0136289 A1
(43) Pub. Date: May 17, 2018

(54) METHOD FOR TESTING AN INVERTER DEVICE OR A POWER CONVERTER DEVICE

(71) Applicant: WIND & SUN TECHNOLOGIES S.L., VILADECANS (BARCELONA) (ES)

(72) Inventor: LORENZ FEDDERSEN, FLENSBURG (DE)

(21) Appl. No.: 15/566,517

(22) PCT Filed: Apr. 13, 2015
(86) PCT No.: PCT/EP2015/057969

§ 371 Date: Oct. 13, 2017

(51) Int. Cl. G01R 31/42

(52) U.S. Cl. CPC G01R 31/42

(57) ABSTRACT

A method for testing an inverter device for converting DC current from DC current generators into AC current, the inverter device comprising a plurality of parallel DC current branches, each DC current branch comprising an inverter (and a DC current input for connection to one of the DC current generators, is characterised in that, in order to test one of the inverters, the DC current input of the inverter to be tested is connected to the DC current input of a different inverter, which is operated in the opposite direction as a rectifier in order to rectify AC current from an AC voltage source and to feed it into the DC current input of the inverter to be tested.

The present invention relates to a method for testing an inverter device for converting DC current from DC current generators into AC current, the inverter device comprising a plurality of parallel DC current branches, each DC current branch comprising an inverter and a DC current input for connection to one of the DC current generators. The invention also relates to a method for testing a current converter device for converting AC current from AC current generators.

Inverter devices for photovoltaic systems generally comprise a plurality of inverters connected in parallel, a corresponding inverter being provided for each DC current generator (solar cell field). If an inverter is repaired or replaced, for example due to a defect, it has to be tested before the system is put back into operation. An inverter is generally replaced or repaired on-site by a service engineer. However, if the corresponding service call lasts until the evening when the sun has already set, the repaired or replaced inverter cannot be tested because the solar electricity generator cannot supply any more DC current. In such cases, the repaired or replaced inverter can be tested the next morning at the very earliest, leading to additional downtimes and considerable additional costs.

U.S. Pat. No. 6,800,964 B2 discloses a method for optimising the efficiency of an inverter device comprising a plurality of inverters connected in parallel, a contactor being provided between the DC current branches of two inverters in each case, which contactor is open or closed depending on the build-up of power in the different DC current branches, a DC current generator being switched over from an active, error-free inverter to a different active, error-free inverter by closing a contactor.

The object of the invention is to provide test methods in which additional downtimes and costs following the repair or replacement of an inverter or converter are avoided.

The invention solves this problem by the features of the independent claims. According to the invention, in order to test one of the inverters, the DC current input thereof is connected to the DC current input of a different inverter, which is operated in the opposite direction as a rectifier in order to rectify AC current from an AC voltage source and to feed it into the DC current input of the inverter to be tested. The other inverter is used as a (DC current) source in this case, and the inverter to be tested is used as a (DC current) sink. In this way, a DC current generator can be simulated from an AC voltage source by means of the other inverter, and the repaired or replaced inverter can be tested at any time, in particular even at night.

If the inverter device is used to feed solar electricity into alternating-voltage mains, the AC voltage source is advantageously formed by the alternating-voltage mains. In the event that alternating-voltage mains are not available, the AC voltage source can advantageously be formed by an off-grid AC generating set. This can preferably be a generator driven by an internal combustion engine, for example a diesel generator.

In one embodiment, a controllable switching apparatus placed between the DC current inputs can be used to connect the DC current inputs.

In an alternative, particularly simple embodiment, an electrically conductive, for example metal, bridge can be manually positioned between the DC current inputs in order to connect the DC current inputs. In this case, the faulty inverter and the other inverter are preferably disconnected from the inverter device before positioning the bridge.

The connection between the DC current inputs can preferably only be re-opened by the intervention of a service engineer at the site of the inverter device. This prevents unintentional opening of the connection before a service engineer has carried out an on-site test to check that the replacement or repaired inverter is functioning correctly.

The invention includes hybrid systems having different types of DC current generators, in particular solar electricity generators and energy accumulators, for example batteries. When there is a relatively high amount of solar power, one or more of the inverters are preferably operated in the opposite direction as rectifiers in order to charge the energy accumulator(s). When there is a relatively low amount of solar power, the inverters are preferably operated to deliver energy stored in the energy accumulator(s) to the AC mains.

One variant of the invention relates to a method for testing a current converter device for converting AC current from AC current generators, for example different generator windings of a wind turbine, the current converter device comprising a plurality of parallel AC current branches, each AC current branch comprising a converter and an AC current input for connection to one of the AC current generators. In this variant, the invention is characterised in that, in order to test one of the converters, the AC current input of the converter to be tested is connected to the AC current input of a different converter, which is operated in the opposite direction in order to convert AC current from an AC voltage source and to feed it into the AC current input of the converter to be tested.

The invention will be explained hereinafter on the basis of preferred embodiments and with reference to the accompanying drawings, in which:

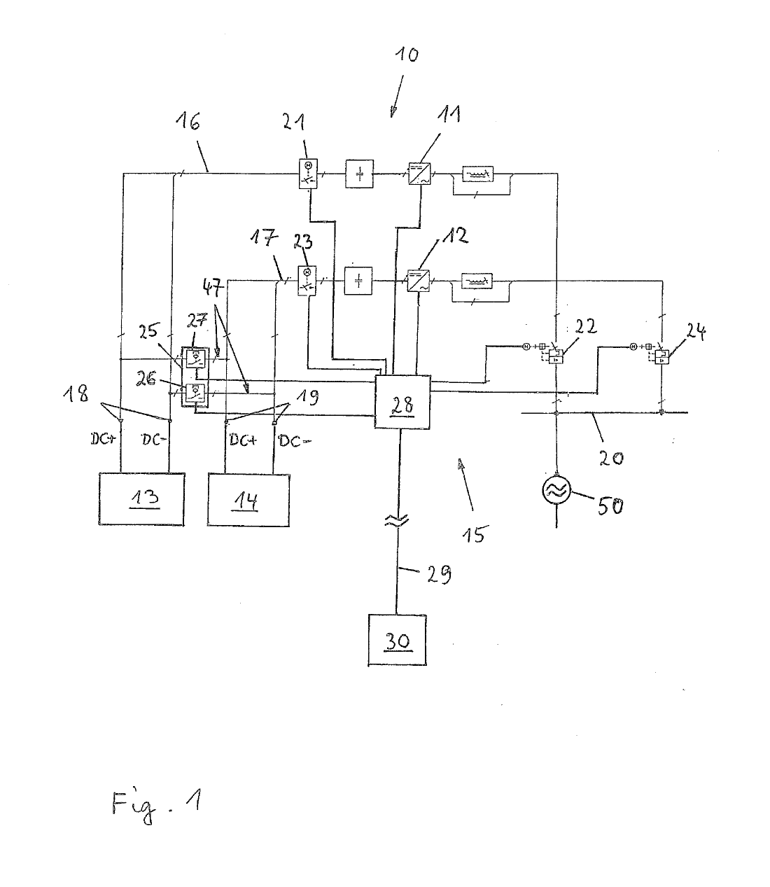

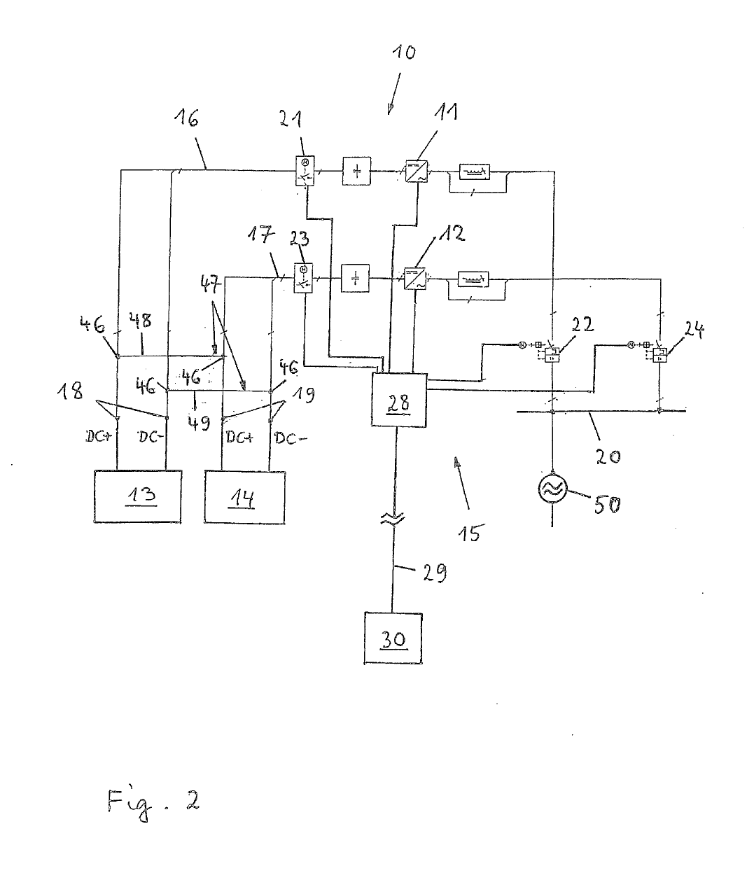

FIGS. 1 and 2 show a schematic circuit diagram for a photovoltaic system in different embodiments of the invention; and

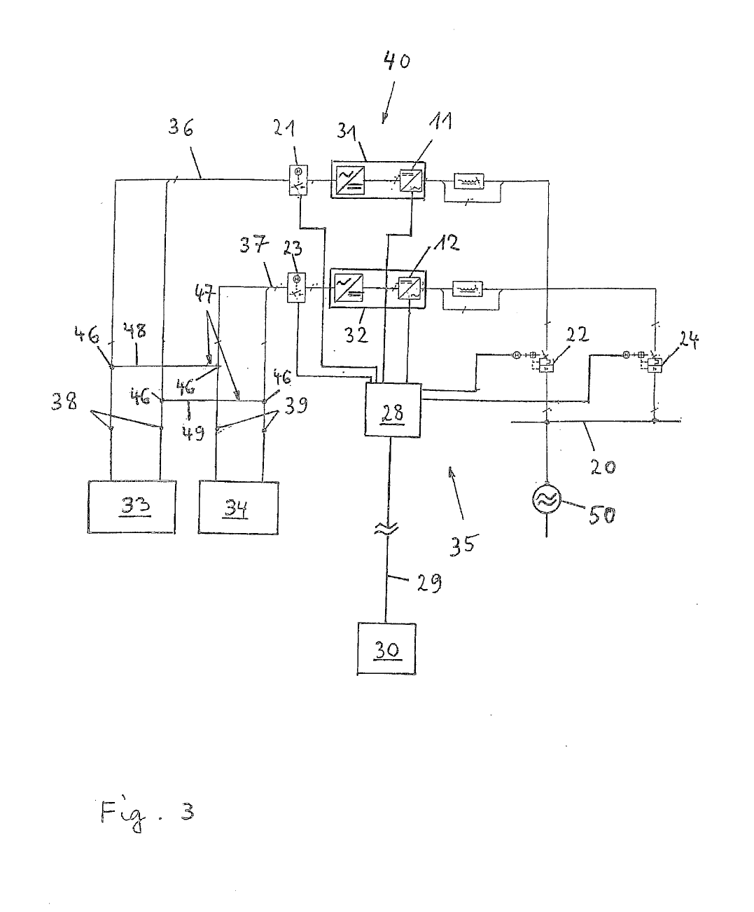

FIG. 3 shows a schematic circuit diagram for a wind turbine in one embodiment of the invention.

The photovoltaic system 10 according to FIG. 1 comprises a plurality of DC current generators 13, 14, in particular solar electricity generators, and an inverter device 15 for converting the DC current generated by the DC current generators 13, 14 into AC current. Each solar electricity generator 13, 14 comprises at least one solar cell field or solar panel. Each solar electricity generator 13, 14 generally contains a plurality of solar cells or photovoltaic cells.

The inverter device 15 comprises a plurality of inverters 11, 12 as central components. Each inverter 11, 12 is connected to a corresponding DC current input 18, 19 by means of lines that form corresponding DC current branches 16, 17. A corresponding DC current generator 13, 14 can be connected to each DC current input 18, 19. Following conversion by means of the inverters 11, 12, the AC current generated is delivered to AC mains 50, AC consumers and/or AC storage mediums, for example, via one or more AC current outputs 20. A controllable switch 21, 22 and 23, 24 is arranged on the DC current side and on the AC current side, of each inverter 11, 12, respectively, in order to be able to individually disconnect the inverters 11, 12 from the inverter device 15, for example in the event of a defect.

The two DC current branches 16, 17 and the two DC current inputs 18, 19 can be connected to one another by means of a controllable switch 25 via a bridge 47. This is explained in more detail in the following: the switch 25 preferably has two poles, i.e. it switches the positive pole of the DC current branches 16, 17 by means of a switching element 27 and the negative pole thereof by means of a switching element 26, the switching elements 26, 27 preferably being coupled. The switches 21 to 25 and the inverters 11, 12 can be activated manually and/or can be controlled by means of an electronic control device 28. The electronic control device 28 is a signal processor or a microprocessor, for example, and can be arranged in the inverter device 15 or generally at any suitable location in the photovoltaic system 10. The electronic control device 28 is also designed to be able to measure and detect an error in one of the inverters 11, 12. The electronic control device 28 is connected to a central remote maintenance system 30 that is arranged at a distance from the photovoltaic system 10 by means of a remote monitoring connection 29.

During normal operation of the system, the switches 21 to 24 are closed and the switch 25 is open. The DC current generated by the DC current generator 13 is conducted via the DC current input 18 and the DC current branch 16 to the inverter 11, where it is converted into AC current and conducted to the AC current output 20. The DC current generated by the DC current generator 14 is conducted via the DC current input 19 and the DC current branch 17 to the inverter 12, where it is converted into AC current and conducted to the AC current output 20.

If the control device 28 detects an error or a defect in one of the inverters 11, 12, said inverter is repaired or replaced on-site by a service engineer. It should be assumed here without limitation that the inverter 12 is repaired or replaced. In this case, the switches 23 and 24 arranged upstream and downstream of the corresponding inverter 12 are opened in order to disconnect the corresponding inverter 12 from the inverter device 15 on both sides, i.e. on the DC current side and on the AC current side.

Once the service engineer has repaired or replaced the inverter 12, the inverter 12 has to be tested to check it is operating properly. For this purpose, the switches 23, 24, 25 are closed by the service engineer on-site. This can be done either manually or by means of an operating terminal for actuating the control device 28. The other inverter 11 is then actuated so as to act as a rectifier for test purposes. AC current is therefore drawn from the AC mains 50, rectified by the current converter 11 and fed into the DC current input 19 and the DC current path 17 of the inverter 12 to be tested via the bridge 47. The DC current fed in is converted by the inverter 12 and can then be fed back into the AC mains 50. If the inverter 12 converts the DC current without any faults, the inverter 12 is error-free and normal operation of the system 10 can be resumed. For this purpose, the switch 25 is opened and the current converter 11 is re-actuated to operate as an inverter 11.

In the test method described, the electrical energy is therefore circulated from the AC mains 50, via the inverter 11, the bridge 47 and back via the inverter 12 to be tested to the AC current side 20 at full capacity. In the test method described, the inverter 11 is used as an AC current source in order to simulate a build-up of power in the AC current generator 14, and the inverter 12 to be tested is used as an AC current sink, i.e. as an inverter in the normal operating mode.

The switch 25 is preferably opened or disconnected on-site by a service engineer for safety reasons. Alternatively, said opening and disconnecting can also be triggered via the remote monitoring connection 29.

Alternatively, a bridge 47 can be provided without the provision of the switch 25, which bridge is manually positioned for the test procedure and then removed again. This embodiment is shown in FIG. 2 by way of example. In this drawing, the bridge 47 consists of two connectors 48, 49 for connecting the two positive inputs DC+ and for connecting the two negative inputs DC− of the inverters 11, 12. Before positioning the bridge 47, the switches 21 to 24 are opened for safety reasons in order to disconnect the inverter 12 to be tested and the other inverter 11 from the inverter device 15. In order to position the bridge 47, the connectors 48, 49 are connected to the DC current lines DC+, DC− by means of two contacts 46, for example screwed contacts, in each case. The connectors 48, 49 can be metal rails or cables, for example. In order to test the inverter 12, the switches 21 to 24 are closed and the other inverter 11 is operated as a rectifier, as described above with reference to FIG. 1. In order to disconnect the bridge 47, at least one of the connectors 48, 49, advantageously both of the connectors 48, 49, is/are removed from the DC current lines DC+, DC− by releasing the contacts 46. The embodiment according to FIG. 2 is particularly advantageous in systems 10 not comprising a switch 25, since complex retrofitting is not required.

The embodiments according to FIGS. 1 and 2 can be applied to the general case of more than two inverters without any problems. In this case, the DC current input of an inverter to be tested is connected to the DC current input of a different inverter (as described above), and the other inverter is operated as a rectifier.

The embodiments according to FIGS. 1 and 2 can be applied to AC current generators 33, 34 instead of to DC current generators 13, 14 without any problems. This is explained with reference to FIG. 3: in these embodiments, the current converter device 35 comprises a plurality of parallel AC current branches 36, 37, each AC current branch 36, 37 comprising a converter 31, 32 and an AC current input 38, 39 for connection to one of the AC current generators 33, 34. The AC current generators 33, 34 can be different windings of the generator of a wind turbine 40, for example. According to the invention, in order to test the repaired converter 32, for example, the bridge 47 is positioned to connect the AC current input 39 of the converter 32 to be tested to the AC current input 38 of the other converter 31. The other converter 31 is then operated in the opposite direction in order to convert AC current from the AC voltage source 50 and to feed it into the AC current input 19 of the converter 32 to be tested.

1-11. (canceled)

12. A method for testing an inverter device configured to convert a plurality of input DC currents from a corresponding plurality of DC current generators into a corresponding plurality of output AC currents, comprising:
providing an inverter device,
wherein the inverter device is configured to convert a plurality of input DC currents from a corresponding plurality of DC current generators into a corresponding plurality of output AC currents,
wherein the inverter device comprises:
a plurality of DC current branches,
wherein the DC current branches of the plurality of DC current branches are in parallel,
wherein each DC current branch of the plurality of DC current branches comprises:
a corresponding inverter of a corresponding plurality of inverters; and
a corresponding DC current input of a corresponding plurality of DC current inputs,
wherein each DC current input of the plurality of DC current inputs is configured to connect to a corresponding DC current generator of the plurality of DC current generators, such that a corresponding input DC current of the DC current generator inputted to the DC current input of the corresponding DC current branch is inputted to the corresponding inverter of the corresponding DC current branch in a first direction, and the inverter operates to:
invert the input DC current of the DC current generator; and
output a corresponding output AC current of the plurality of output AC currents;
connecting a first DC current input of a first DC current branch of the plurality of DC current branches to a second DC current input of a second DC current branch of the plurality of DC current branches;
inputting a test input AC current from an AC voltage source to the second inverter of the second DC current branch in a second direction opposite to the first direction such that the second inverter operates to:
rectify the test input AC current; and
output a test DC current,
wherein the test DC current is outputted from the second DC current input of the second DC current branch and inputted to the first DC current input of the first DC current branch, such that the test DC current inputted to the first DC current input of the first DC current branch is inputted to the first inverter of the first DC current branch in the first direction, and the first inverter of the first DC current branch operates to:
invert the test DC current inputted to the first inverter; and
output a test output AC current; and
testing the first inverter of the first DC current branch based on the test input AC current and the test output AC current.

13. The method according to claim 12,
wherein the AC voltage source is an AC mains.

14. The method according to claim 12,
wherein the AC voltage source is an off-grid AC generating set.

15. The method according to claim 14,
wherein the AC voltage source is a generator driven by an internal combustion engine.

16. The method according to claim 12,
wherein connecting the first DC current input of the first DC current branch to the second DC current input of the second DC current branch comprises:
placing a controllable switch between the first DC current input of the first DC current branch and the second DC current input of the second DC current branch; and
connecting the first DC current input of the first DC current branch to the second DC current input of the second DC current branch via the controllable switch.

17. The method according to claim 12,
wherein connecting the first DC current input of the first DC current branch to the second DC current input of the second DC current branch comprises:
manually positioning an electrically conductive bridge between the first DC current input of the first DC current branch and the second DC current input of the second DC current branch; and
connecting the first DC current input of the first DC current branch to the second DC current input of the second DC current branch via the electrically conductive bridge.

18. The method according to claim 17, further comprising:
before manually positioning the electrically conductive bridge, disconnecting the first inverter from the inverter device and disconnecting the second inverter from the inverter device.

19. The method according to claim 12,
wherein, after connecting the first DC current input of the first DC current branch and the second DC current input of the second DC current branch, the connection between the first DC current input of the first DC current branch and the second DC current input of the second DC current branch can only be disconnected by an intervention of a person at a site of the inverter device.

20. The method according to claim 12, further comprising:
inputting one or more charging AC currents to a corresponding one or more inverters of the plurality of inverters in the second direction, such that the one or more inverters operate to:
rectify the one or more charging AC currents; and
output a corresponding one or more charging DC currents; and
charging at least one energy accumulator via the one or more charging DC currents.

21. The method according to claim 20, further comprising:
inputting a corresponding at least one output DC current from the at least one energy accumulator to a corresponding at least one DC current input of a corresponding at least one DC current branch of the plurality of DC current branches, such that the at least one output DC current is inputted to the corresponding at least one inverter of the at least one DC current branch and the at least one inverter operates to:
invert the at least one output DC current inputted to the at least one inverter; and
output a corresponding at least one output AC current,
so as to convert energy stored in the at least one energy accumulator into the at least one output AC current.

22. A method for testing a current converter device configured to convert a plurality of input AC currents from a corresponding plurality of AC current generators into a corresponding plurality of output AC currents, comprising:
providing a current converter device,
wherein the current converter device is configured to convert a plurality of input AC currents from a corresponding plurality of AC current generators into a corresponding plurality of output AC currents,
wherein the current converter device comprises:
a plurality of AC current branches,
wherein the AC current branches of the plurality of AC current branches are in parallel,
wherein each AC current branch of the plurality of AC current branches comprises:
a corresponding converter of a corresponding plurality of converters; and
a corresponding AC current input of a corresponding plurality of AC current inputs,
wherein each AC current input of the plurality of AC current inputs is configured to connect to a corresponding AC current generator of the corresponding plurality of AC current generators;
connecting a first AC current input of a first AC current branch of the plurality of AC current branches to a second AC current input of a second AC current branch of the plurality of AC current branches, such that a corresponding input AC current of the AC current generator inputted to the AC current input of the corresponding AC current branch is inputted to the corresponding converter of the corresponding AC current branch in a first direction, and the converter operates to:
convert the input AC current of the AC current generator; and
output a corresponding output AC current of the plurality of output AC currents;
inputting a test input AC current from an AC voltage source to the second converter of the second AC current branch in a second direction opposite to the first direction such that the second converter operates to:
convert the test input AC current; and
output a test AC current,
wherein the test AC current is outputted from the second AC current input of the second AC current branch and inputted to the first AC current input of the first AC current branch, such that the test AC current inputted to the first AC current input of the first AC current branch is inputted to the first converter in the first direction, and the first converter operates to:
convert the test AC current; and
output a test output AC current; and
testing the first converter of the first AC current branch based on the test input AC current and the test output AC current.
